(19) United States
(12) Patent Application Publication
(10) Pub. No.: US 2019/0386869 A1
(43) Pub. Date: Dec. 19, 2019

(54) METHOD AND APPARATUS FOR CALIBRATING MISMATCHING BETWEEN IN-PHASE COMPONENT AND QUADRATURE COMPONENT IN WIRELESS COMMUNICATION SYSTEM

(71) Applicant: Samsung Electronics Co., Ltd., Gyeonggi-do (KR)

(72) Inventors: Tuan Manh DAO, Gyeonggi-do (KR); Kihong MIN, Gyeonggi-do (KR); Yonghoon KIM, Gyeonggi-do (KR); Yuichi AOKI, Gyeonggi-do (KR)

(73) Assignee: Samsung Electronics Co., Ltd.

(21) Appl. No.: 16/445,774

(22) Filed: Jun. 19, 2019

(30) Foreign Application Priority Data
Jun. 19, 2018 (KR) 10-2018-0070481

(51) Int. Cl. H04L 27/38; H04B 1/30; H03D 3/00

(52) U.S. Cl. CPC H04L 27/3863; H03D 3/009; H04B 1/30

(57) ABSTRACT

Method of operating electronic device including transmitter and receiver in wireless communication system and the electronic device are provided. The method includes acquiring signal passing through intermediate path between transmitter and receiver; estimating phase change in intermediate path, based on the signal and a reception signal predicted by a modeled system; and determining in-phase/quadrature (I/Q) mismatch parameters indicating a mismatch of I components and Q components of the transmitter and the receiver from the phase change. The electronic device includes a transmitter; a receiver; and at least one processor, configured to acquire a signal passing through an intermediate path between the transmitter and the receiver, estimate a phase change in the intermediate path, based on the signal and a reception signal predicted by a modeled system, and determine I/Q mismatch parameters indicating a mismatch of I components and Q components of the transmitter and the receiver from the phase change.

### CROSS-REFERENCE TO RELATED APPLICATION(S)

This application is based on and claims priority under 35 U.S.C. 119 to Korean Patent Application No. 10-2018-0070481, filed on Jun. 19, 2018, in the Korean Intellectual Property Office, the entire disclosure of which is herein incorporated by reference.

### BACKGROUND

### 1) Field

The disclosure relates generally to a wireless communication system, and more particularly, to a method and an apparatus for calibrating mismatching between an in-phase (I) component and a quadrature (Q) component in a wireless communication system.

### 2) Description of Related Art

Recent wireless communication systems use quadrature modulation simultaneously using an I component and a Q component, which are orthogonal to each other, for up conversion of transitioning a signal to be transmitted from a baseband to a passband and down conversion of transitioning a signal from a passband to a baseband. Quadrature modulation has an advantage in that double signals can be transmitted using one carrier, but may still deteriorate performance of a communication system because of the generation of mutual interface between I/Q signals when a mismatch is generated between the I component and the Q component of a mixer.

I/Q mismatch may be divided into a gain mismatch and a phase mismatch. Gain mismatch indicates that there is a difference between sizes of an I component and a Q component of a mixer. Phase mismatch indicates that a phase difference between I/Q outputs of the mixer is not 90 degrees and, thus, the I/Q outputs are not orthogonal.

When I/Q mismatch is generated in a quadrature modulator of a transceiver, an error vector magnitude (EVM) deteriorates and a packet error rate (PER) increases, thereby degrading the total performance of the communication system. Particularly, recent wireless communication systems such as a wireless local area network (WLAN), a wireless personal area network (WPAN), long term evolution (LTE), and new radio (NR) use high-order modulation such as 16 quadrature amplitude modulation (QAM), 64 QAM, and 256 QAM in order to increase the amount of data transmission. However, a higher-order modulation scheme is more sensitive to transceiver I/Q mismatch. Accordingly, in order to guarantee smooth communication, calibration of the I/Q mismatch of the transceiver is needed.

The above information is presented as background information only to assist with an understanding of the disclosure. No determination has been made, and no assertion is made, as to whether any of the above might be applicable as prior art with regard to the disclosure.

### SUMMARY

An aspect of the disclosure provides, a method and an apparatus for easily performing I/Q mismatch calibration without complex hardware implementation according to a separate I/Q training sequence.

Another aspect of the disclosure provides, a method and an apparatus for performing I/Q mismatch calibration within a short period of time by preventing repetition of performance evaluation performed until an optimal value is acquired.

Another aspect of the disclosure provides, a method and an apparatus for performing I/Q mismatch calibration through both a transmitter and a receiver, only a transmitter, or only a receiver according to circumstances.

In accordance with an aspect of the disclosure, a method of operating an electronic device including a transmitter and a receiver in a wireless communication system is provided. The method includes acquiring a signal passing through an intermediate path between the transmitter and the receiver; estimating a phase change in the intermediate path, based on the signal and a reception signal predicted by a modeled system; and determining I/Q mismatch parameters indicating a mismatch of I components and Q components of the transmitter and the receiver from the phase change.

In accordance with another aspect of the disclosure, an electronic device in a wireless communication system is provided. The electronic device includes a transmitter; a receiver; and at least one processor, configured to acquire a signal passing through an intermediate path between the transmitter and the receiver, estimate a phase change in the intermediate path, based on the signal and a reception signal predicted by a modeled system, and determine I/Q mismatch parameters indicating a mismatch of I components and Q components of the transmitter and the receiver from the phase change.

### BRIEF DESCRIPTION OF THE DRAWINGS

The above and other aspects, features, and advantages of certain embodiments of the disclosure will be more apparent from the following description, taken in conjunction with the accompanying drawings, in which:

FIG. 1 A illustrates a signal having no mismatch between an I component and a Q component (I/Q mismatch) in a wireless communication system;

FIG. 1B illustrates a signal having no mismatch between an I component and a Q component in a wireless communication system;

FIG. 2A illustrates a signal having an I/Q mismatch in a wireless communication system;

FIG. 2B illustrates a signal having an I/Q mismatch in a wireless communication system;

FIG. 3 is a flowchart of a method of calibrating an I/Q mismatch in a wireless communication system according to an embodiment;

FIG. 4A illustrates a device for calibrating I/Q mismatches of a transmitter and a receiver in a wireless communication system according to an embodiment;

FIG. 4B illustrates a device for calibrating an I/Q mismatch of a transmitter in a wireless communication system according to an embodiment;

FIG. 4C illustrates a device for calibrating an I/Q mismatch of a receiver in a wireless communication system according to an embodiment;

FIG. 5 illustrates a system for calibrating an I/Q mismatch in a wireless communication system according to an embodiment;

FIG. 6 illustrates a system for estimating a loopback angle for calibrating an I/Q mismatch in a wireless communication system according to an embodiment;

FIG. 7 illustrates a sum of I/Q power for estimating a loopback angle for calibrating an I/Q mismatch in a wireless communication system according to an embodiment;

FIG. 8 illustrates a system for normalizing a signal in order to estimate a loopback angle for calibrating an I/Q mismatch in a wireless communication system according to an embodiment;

FIG. 9A illustrates a device for calibrating I/Q mismatches of a transmitter and a receiver in a wireless communication system according to an embodiment;

FIG. 9B is a flowchart of a method of calibrating I/Q mismatches of a transmitter and a receiver in a wireless communication system according to an embodiment;

FIG. 10 is a flowchart of a method of calibrating an I/Q mismatch of a transmitter in a wireless communication system according to an embodiment;

FIG. 11 is a flowchart of a method of calibrating an I/Q mismatch of a receiver in a wireless communication system according to an embodiment;

FIG. 12A illustrates a power spectrum density of a transmission signal or a reception signal when I/Q mismatch calibration is performed or not performed in a wireless communication system according to an embodiment;

FIG. 12B illustrates a power spectrum density of a transmission signal or a reception signal when I/Q mismatch calibration is performed or not performed in a wireless communication system according to an embodiment;

FIG. 12C illustrates a power spectrum density of a transmission signal or a reception signal when I/Q mismatch calibration is performed or not performed in a wireless communication system according to an embodiment;

FIG. 12D illustrates a power spectrum density of a transmission signal or a reception signal when I/Q mismatch calibration is performed or not performed in a wireless communication system according to an embodiment;

FIG. 13A illustrates gain extraction errors of a transmission signal and a reception signal after an I/Q mismatch is calibrated in a wireless communication system according to an embodiment;

FIG. 13B illustrates phase extraction errors of a transmission signal and a reception signal after an I/Q mismatch is calibrated in a wireless communication system according to an embodiment; and

FIG. 14 illustrates image rejection ratios (IRRs) of an I/Q mismatch calibration method according to an embodiment.

### DETAILED DESCRIPTION

The terms used in the disclosure are only used to describe certain embodiments, but are not intended to limit the disclosure. A singular expression may include a plural expression unless they are definitely different in a context. Unless defined otherwise, all terms used herein, have the same meanings as those commonly understood by a person skilled in the art to which the disclosure pertains. Such terms as those defined in a generally used dictionary may be interpreted to have the meanings equal to the contextual meanings in the relevant field of art, but are not intended to be interpreted to have ideal or excessively formal meanings unless clearly defined in the disclosure. In some cases, even a term defined in the disclosure is not intended to be interpreted to exclude embodiments of the disclosure.

Hereinafter, various embodiments of the disclosure are described based on hardware. However, various embodiments of the disclosure may include both hardware and software and, thus, the various embodiments of the disclosure are not intended to exclude software.

The disclosure relates to a method and an apparatus for calibrating a mismatch between an I component and a Q component (I/Q mismatch) in a wireless communication system. Specifically, the disclosure discloses performing I/Q mismatch calibration within a short period of time without a special training sequence by hardware.

The terms referring to a signal used in the following description, control information, network entities, and elements of a device are used only for convenience of description. Accordingly, the disclosure is not intended to be limited to the following terms and other terms having the same meanings may be used.

In a wireless communication system using quadrature modulation, the I/Q mismatch may cause system performance deterioration. Accordingly, through an operation of detecting and calibrating the I/Q mismatch, system performance deterioration may be prevented.

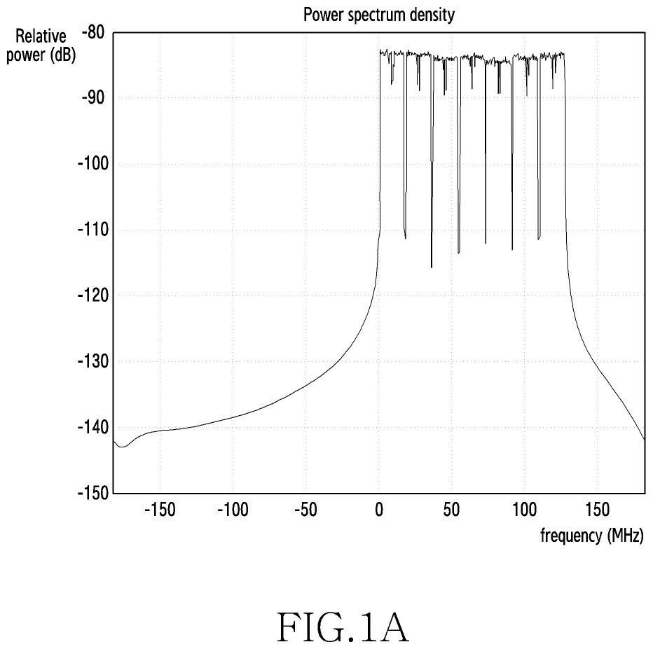

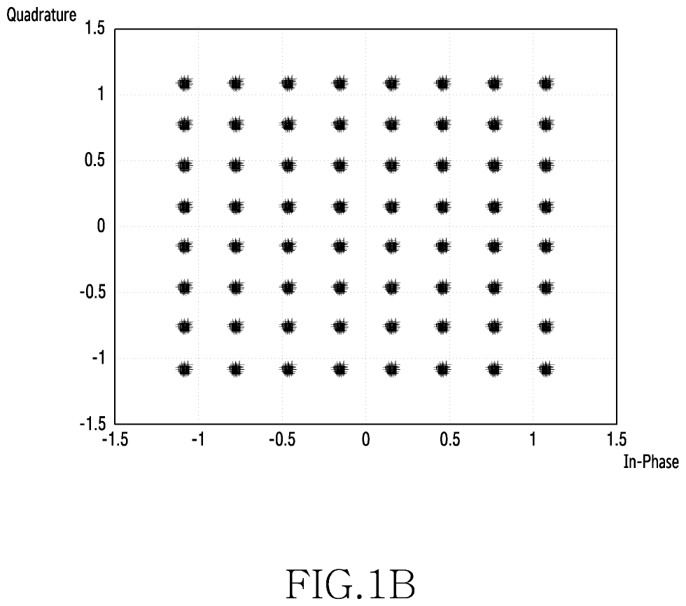

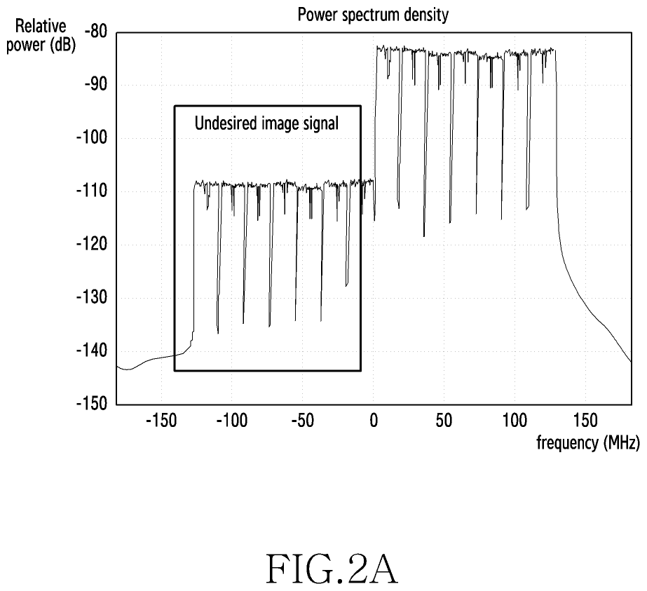

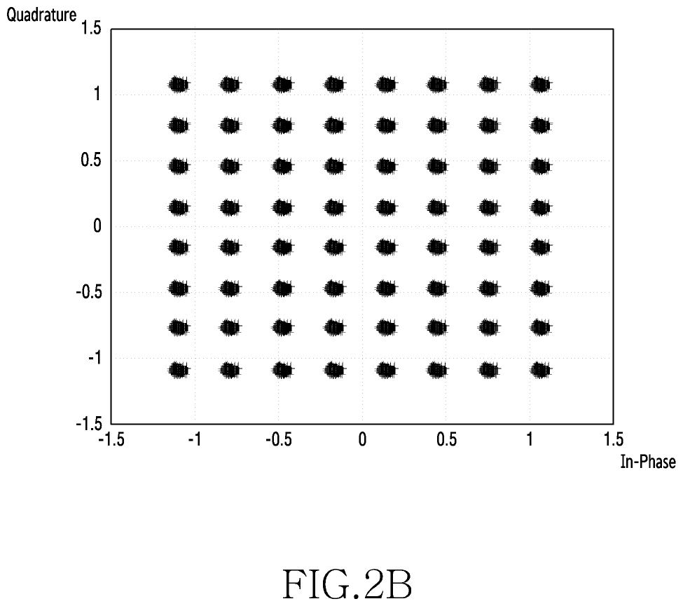

FIG. 1A illustrates a signal having no I/Q mismatch in a wireless communication system. FIG. 1B illustrates a signal having no I/Q mismatch in a wireless communication system. FIG. 2A illustrates a signal having an I/Q mismatch in a wireless communication system. FIG. 2B illustrates a signal having an I/Q mismatch in a wireless communication system.

FIG. 1 A illustrates a power spectrum density through relative power according to a frequency of an original signal.

Referring to FIG. 1A, when there is no I/Q mismatch, there is a signal in a frequency band of the original signal and there is no signal in an image frequency band.

FIG. 1B illustrates a constellation according to a modulation scheme.

Referring to FIG. 1B, 64 different signals are distinguished from each other according to a modulation scheme of 64 QAM.

FIG. 2A illustrates a power spectrum density of a transmitted signal when an I/Q mismatch is generated during a process of performing quadrature modulation on the original signal of FIG. 1A. More specifically, FIG. 2A illustrates an I/Q mismatch of ε_{Tx}=0.1; θ_{Tx}=2 deg being generated.

Referring to FIG. 2A, there is a signal in a frequency band of the original signal and in an image signal band due to the I/Q mismatch. Consequently, an undesired image signal is also transmitted.

FIG. 2B illustrates a constellation according to a modulation scheme when the I/Q mismatch is generated. More specifically, FIG. 2B illustrates the I/Q mismatch of ε_{Tx}=0.1: θ_{Tx}=2 deg being generated.

Referring to FIG. 2B, in the constellation of FIG. 2B, noise components increase as compared to FIG. 1B and, thus, an EVM deteriorates.

In a quadrature modulator and demodulator, an I/Q mismatch includes a mismatch of a gain and a phase. The I/Q mismatch significantly influences system performance. Referring to FIGS. 2A and 2B, poor image rejection is generated by an I/Q mismatch and EVM is seriously deteriorated. Accordingly, in order to improve system performance, the I/Q mismatch should be calibrated.

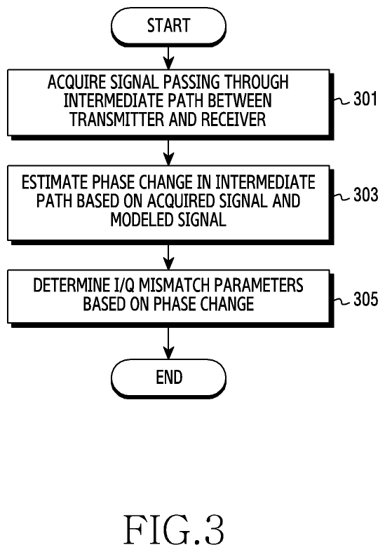

FIG. 3 is a flowchart of a method of calibrating an I/Q mismatch according to an embodiment. Specifically, FIG. 3 is a flowchart illustrating a method of calibrating an I/Q mismatch by an electronic device including a transmitter and a receiver in a wireless communication system.

Referring to FIG. 3, in step 301, the electronic device acquires a test signal passing through at least the transmitter and the receiver and an intermediate path between the transmitter and the receiver. Both the transmitter and the receiver may be targets to be measured or calibrated for the I/Q mismatch, or one of the transmitter and the receiver may be a target to be measured or calibrated for the I/Q mismatch. When both the transmitter and the receiver are targeted to be measured or calibrated for the I/Q mismatch, the intermediate path may be a loopback path between a transmission path and a reception path of one device. The loopback path may include a first loopback path and a second loopback path. When one of the transmitter and the receiver are targeted to be measured or calibrated for the I/Q mismatch, the intermediate path may be a radio channel, that is, an over-the-air (OTA) path. The receiver or the transmitter may be a separate device (e.g., a signal generator, a signal measurer, a spectrum analyzer, or an oscilloscope) used to measure or calibrate the I/Q mismatch of the transmitter or the receiver. Accordingly, the electronic device may acquire a signal passing through the transmitter, the intermediate path, and the receiver, a signal passing through the transmitter and the intermediate path, or a signal passing through the intermediate path and the receiver. A signal acquired after passing through the intermediate path may be referred to as a “first received signal”, an “actually received signal”, or a “captured signal”.

In step 303, the electronic device estimates an amount of a phase change in the intermediate path based on the received signal and the test signal. The amount of the phase change in the intermediate path may be referred to as a “loopback angle”, an “OTA delay”, or an “OTA phase angle”. For example, the electronic device may estimate the amount of the phase change in the intermediate path through a system modeled to have the equivalent characteristic as the target to be measured for the I/Q mismatch.

The electronic device may acquire a virtually received signal by deriving the result obtained after the test signal passes through the modeled system and estimating the amount of the phase change in the intermediate path based on a sum of power of the virtually received signal and the captured signal. The amount of the phase change may be determined as an amount of a phase change applied to the virtual received signal that maximizes the sum of power. The signal derived as the result from the modeled system may be referred to as a “second received signal”, a “virtually received signal”, a “tuning signal”, or a “modeled signal”.

In step 305, the electronic device determines I/Q mismatch parameters from the amount of the phase change in the intermediate path. The I/Q mismatch parameters include two or more of a first parameter indicating a gain mismatch of the transmitter, a second parameter indicating a gain mismatch of the receiver, a third parameter indicating a phase mismatch of the transmitter, and a fourth parameter indicating a phase mismatch of the receiver. The electronic device may determine I/Q mismatch parameters from the amount of change based on the relationship between the I/Q parameters derived from the estimated amount of the phase change in the intermediate path and a normalized power value of the captured signal. For example, the electronic device may generate relationship formulas indicating relationships between the I/Q mismatch parameters and the normalized power value and determine the I/Q mismatch parameters through the relationship formulas. The relationship formulas may include a relationship formula of a real number component and an imaginary number component of normalized power values.

In FIG. 3, the amount of the phase change in the intermediate path is determined using the modeled signal. To this end, the sum of power of the captured signal and the modeled signal is calculated. The I/Q mismatch parameters applied to the modeled signal may be set as predefined values. For example, the predefined values may be “0” or particular values.

When both the transmitter and the receiver are targets to be measured or calibrated for the I/Q mismatch, four I/Q mismatch parameters may be determined. In this case, a minimum of four relation formulas may be required and two intermediate paths (for example, two loopback paths) may be used therefor. The electronic device may estimate amounts of the phase change in the two intermediate paths and generate relationship formulas corresponding to the two intermediate paths.

The receiver may be an oscilloscope for calibrating the I/Q mismatch of the transmitter. The electronic device may configure I/Q mismatch parameters of the receiver as 0 and determine I/Q mismatch parameters of the transmitter. Further, the transmitter may be a signal generator for calibrating the I/Q mismatch of the receiver. The electronic device may configure the I/Q mismatch parameters of the transmitter as 0 and determine the I/Q mismatch parameter of the receiver.

A method of calibrating the I/Q mismatch according to an embodiment of the present disclosure has the following advantages as compared to a conventional method of calibrating the I/Q mismatch.

In a conventional method of calibrating the I/Q mismatch, a process of repeatedly evaluating performance until an optimal value is found without determining I/Q mismatch parameters within a short period of time since a loopback angle cannot be known. However, in the method of calibrating the I/Q mismatch according to an embodiment of the disclosure, the I/Q mismatch parameters may be determined within a short period of time based on the loopback angle since the loopback angle may be estimated.

In the conventional method of calibrating the I/Q mismatch, the I/Q calibration may be performed on only one of the transmitter and the receiver. However, in a method of calibrating the I/Q mismatch according to an embodiment of the disclosure, the I/Q calibration may be performed on both the transmitter and the receiver. Further, the I/Q calibration may be selectively performed on one of the transmitter and the receiver as necessary.

In the conventional method of calibrating the I/Q mismatch, a special training sequence is applied and, thus, a complex and expensive hardware device is needed. However, in a method of calibrating the I/Q mismatch according to an embodiment of the disclosure, I/Q mismatch parameters are determined by a simple operation procedure and thus a simple and cheap hardware component may be sufficient.

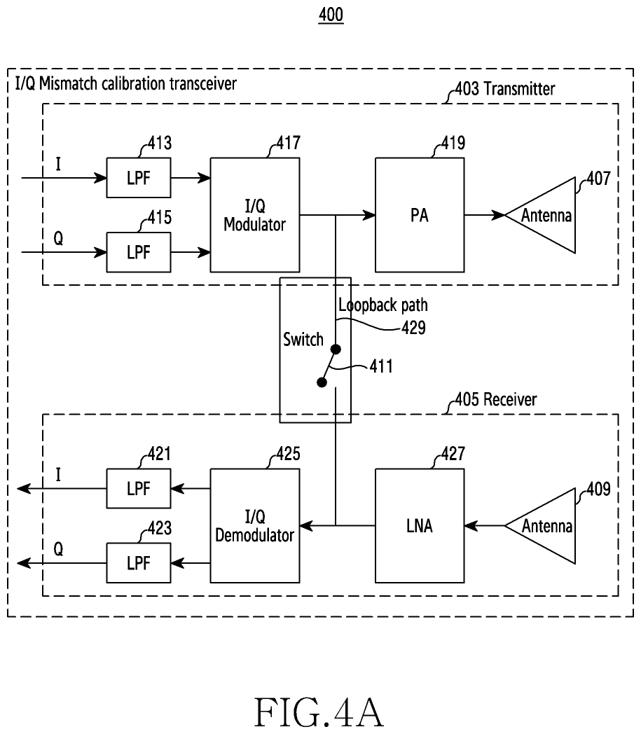

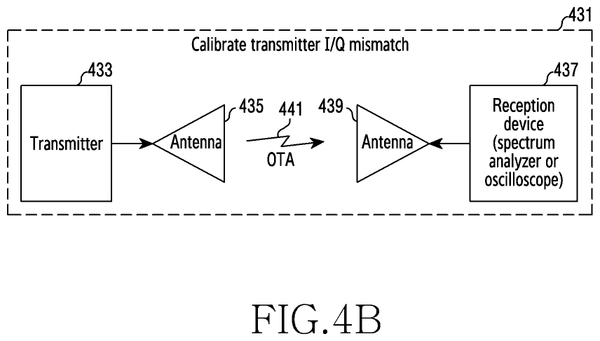

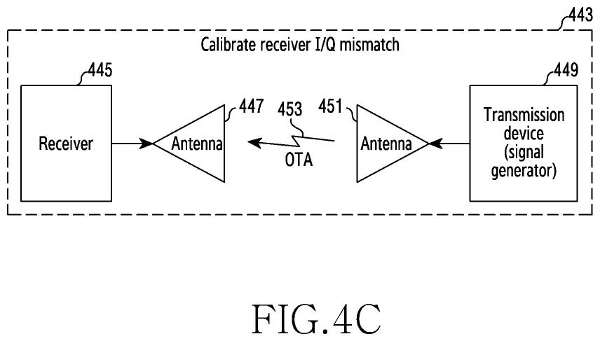

FIG. 4A illustrates a device for calibrating I/Q mismatches of a transmitter and a receiver according to an embodiment. Specifically, FIG. 4A illustrates a structure of an electronic device 400 for calibrating I/Q mismatches for both the transmitter and the receiver.

Referring to FIG. 4A, the electronic device 400 is a transceiver including a transmitter 403 and a receiver 405. The electronic device 400 may calibrate the I/Q mismatch for both the transmitter 403 and the receiver 405.

The electronic device 400 may further include at least one processor. The at least one processor may be operatively connected to the transmitter 403 and the receiver 405 and may control the transmitter 403 and the receiver 405.

The transmitter 403 allows test signals of I and Q to pass through low pass filters (LPFs) 413 and 415 and then be inputted into an I/Q modulator 417. The signal passing through the I/Q modulator 417 passes through a power amplifier (PA) 419 and is then transmitted through an antenna 407.

The receiver 405 allows a signal received through an antenna 409 to pass through a low noise amplifier (LNA) 427 and then be inputted into an I/Q demodulator 425. The signal passing through the I/Q demodulator 425 passes through low pass filters 421 and 423 and is then received as I/Q signals.

The signal passing through the I/Q modulator 417 of the transmitter 403 may be input into the I/Q demodulator 425 of the receiver 405 through a loopback path 429 opened/closed by a switch 411. According to circumstances, the loopback path 429 may include a first loopback path and a second loopback path.

The electronic device 400 may estimate a loopback angle by comparing a signal received through the loopback path 429 with a received signal predicted by the modeled system and then determine I/Q mismatch parameters of the transmitter 403 and the receiver 405. The I/Q mismatch parameters include a gain mismatch parameter ε_{Tx} of the transmitter, a gain mismatch parameter ε_{Rx} of the receiver, a phase mismatch parameter θ_{Tx} of the transmitter, and a phase mismatch parameter θ_{Rx} of the receiver.

The electronic device 400 estimates the loopback angle based on an I/Q test signal transmitted by the transmitter 403 and the I/Q signal received by the receiver 405. The loopback angle may include a first loopback angle estimated based on the I/Q signal received through a first loopback path and the I/Q test signal and a second loopback angle estimated based on the I/Q signal received through a second loopback path and the I/Q test signal. The loopback angle is an angle that maximizes a sum of power of the received I/Q signal and an I/Q received signal predicted by the modeled system. After determining the loopback angle, the electronic device 400 may calculate I/Q mismatch parameters through a predetermined equation based on the loopback angle.

FIG. 4B illustrates a device for calibrating an I/Q mismatch of a transmitter according to an embodiment.

Referring to FIG. 4B, the electronic device 431 includes the transmitter 433 and a reception device (or a receiver) 437. The transmitter 433 transmits an I/Q test signal through an antenna 435 wirelessly, that is, OTA as indicated by reference numeral 441. The reception device 437 receives the I/Q test signal through an antenna 439 OTA as indicated by reference numeral 441. The reception device 437 may be a spectrum analyzer or an oscilloscope.

The wireless device 431 may configure I/Q mismatch parameters of the reception device 437 as 0 and determine I/Q mismatch parameters of the transmitter 433. A process in which the wireless device 431 determines the I/Q mismatch parameters of the transmitter 433 is similar to that of FIG. 4A. The wireless device 431 estimates an OTA phase angle based on the I/Q test signal transmitted by the transmitter 433 and the I/Q signal received by the reception device 437. The OTA phase angle may correspond to a loopback angle. Accordingly, a process of acquiring the OTA phase angle is the same as the process of acquiring the loopback angle. However, when the OTA phase angle is acquired, the reception device 437 has already passed through the I/Q calibration, so that only the I/Q mismatch of the transmitter is generated during the process of transmitting the signal without the generation of the I/Q mismatch during the process of receiving the signal. Accordingly, among the four I/Q mismatch parameters ε_{Tx}, ε_{Rx}, θ_{Tx}, and θ_{Rx}, the I/Q mismatch parameters ε_{Rx} and θ_{Rx} related to reception may be 0 and only the I/Q mismatch parameters ε_{Tx} and θ_{Tx} related to transmission have meaningful values. The OTA phase angle is an angle that maximizes a sum of power of the received I/Q signal and the I/Q received signal predicted by the modeled system. After determining the OTA phase angle, the electronic device 431 may calculate the I/Q mismatch parameters ε_{Tx} and θ_{Tx} through a predetermined equation based on the OTA phase angle.

FIG. 4C illustrates a device for calibrating an I/Q mismatch of a receiver according to an embodiment.

Referring to FIG. 4C, the electronic device 443 includes the receiver 445 and a transmission device (or transmitter) 449. The transmitter 449 transmits an I/Q test signal through an antenna 451 wirelessly, that is, OTA as indicated by reference numeral 453. A receiver 445 receives the I/Q test signal through an antenna 447 OTA as indicated by reference numeral 453. The transmission device 449 may be a signal generator.

The wireless device 443 may configure I/Q mismatch parameters of the transmission device 449 as 0 and determine I/Q mismatch parameters of the receiver 445. A process in which the wireless device 443 determines the I/Q mismatch parameters of the receiver 445 is similar to that of FIG. 4A. The wireless device 443 estimates an OTA phase angle based on the I/Q test signal transmitted by the transmission device 449 and the I/Q signal received by the reception device 445. The OTA phase angle corresponds to a loopback angle. Accordingly, a process of acquiring the OTA phase angle is the same as the process of acquiring the loopback angle. However, when the OTA phase angle is acquired, the transmission device 449 has already passed through the I/Q calibration, so that only the I/Q mismatch of the receiver exists during the process of receiving the signal without the generation of the I/Q mismatch during the process of transmitting the signal. Accordingly, among the four I/Q mismatch parameters ε_{Tx}, ε_{Rx}, θ_{Tx}, and θ_{Rx} the I/Q mismatch parameters ε_{Tx} and θ_{Tx} related to transmission may be 0 and only the I/Q mismatch parameters ε_{Rx} and θ_{Rx} related to reception have meaningful values. The OTA phase angle is an angle that maximizes a sum of power of the received I/Q signal and the I/Q received signal predicted by the modeled system. After determining the OTA phase angle, the electronic device 443 may calculate the I/Q mismatch parameters ε_{Rx} and θ_{Rx} through a predetermined equation based on a loopback angle.

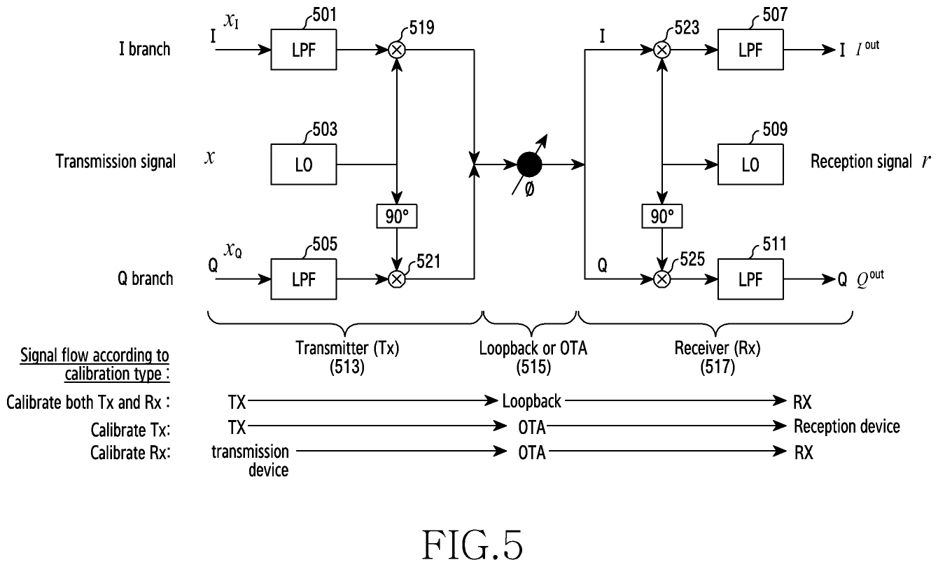

FIG. 5 illustrates a system for calibrating an I/Q mismatch according to an embodiment.

In the embodiments of FIGS. 4A to 4C, the electronic devices calculate I/Q mismatch parameters through the method illustrated in FIG. 5.

Referring to FIG. 5, the loopback path of FIG. 4A or the delay due to OTA of FIGS. 4B and 4C may be modeled to a variable phase.

A transmission signal to be transmitted by a transmitter 513 may be expressed by Equation (1) below.

x=x_{I}+jx_{Q} Equation (1)

In Equation (1) above, x denotes a transmission signal to be transmitted by the transmitter 513, x_{I} denotes a real number component of x, and x_{Q} denotes an imaginary number component of x.

A signal of the real number component and the imaginary number component x_{Q} and x_{I} of the transmission signal x is input into an I branch and a Q branch of the transmitter 513. x_{I} and x_{Q} pass through LPF 501 and LPF 505, respectively, and then are converted into passband signals by up converter 519 and up converter 521, respectively. A signal of a mixer 503 is also input into the up converter 519 and the up converter 521 at phases of 0 degrees and 90 degrees, respectively. After passing through the up converter 519, x_{I} is multiplied by

$$( 1 + \frac{{ɛ}_{Tx}}{2} ) \cdot cos ( 2 π {f}_{c} t + \frac{{θ}_{Tx}}{2} ) .$$

After passing through the up converter 521, x_{Q} is multiplied by

$$- ( 1 - \frac{{ɛ}_{Tx}}{2} ) \cdot sin ( 2 π {f}_{c} t - \frac{{θ}_{Tx}}{2} ) .$$

ε_{Tx} denotes a mismatch of an amplitude in the transmitter 513 and θ_{Tx} denotes a mismatch of a phase in the transmitter 513.

The signals passing through the up converter 519 and the up converter 521 are transmitted to the receiver 517 through loopback or OTA 515. Specifically, the signals are transmitted to the receiver 517 through the loopback when both the transmitter (TX) 513 and the receiver (RX) 517 are calibrated, and transmitted to the receiver 517 OTA when one of the TX 513 and the RX 517 is calibrated. The loopback route or the OTA delay may be modeled in a parameter form.

A real number component and an imaginary number component of the signal input into the receiver 517 are input into an I branch and a Q branch of the receiver 517, respectively.

After passing through the LPF 501 and the LPF 505, the real number component and the imaginary number component of the signal input into the receiver 517 are converted into baseband signals by down converter 523 and down converter 525. A signal of a mixer 509 is also input into the down converter 523 and the down converter 525 at phases of 0 degrees and 90 degrees, respectively. The baseband signals passing through the down converter 523 and the down converter 525 pass through LPF 507 and LPF 511. The signals passing through the LPF 507 and LPF 511 are included in a real component I^{out} and an imaginary number component Q^{out} of a reception signal r, respectively. That is, the reception signal r received by the receiver 517 may be expressed by Equation (2) below.

r=I^{out}+jQ^{out} Equation (2)

In Equation (2) above, r denotes a reception signal, I^{out} denotes a real number component of r, and Q^{out} denotes an imaginary number component of r.

After passing through the down converter 523 and the low pass filter 507, I^{out} is a value obtained by multiplying the real number component of the signal input into the receiver 517 and

$$( 1 + \frac{{ɛ}_{Rx}}{2} ) \cdot cos ( 2 π {f}_{c} t + \frac{{θ}_{Rx}}{2} ) .$$

After passing through the down converter 525 and the low pass filter 511, Q^{out} is a value obtained by multiplying the imaginary number component of the signal input into the receiver 517 and

$$- ( 1 - \frac{{ɛ}_{Rx}}{2} ) \cdot sin ( 2 π {f}_{c} t - \frac{{θ}_{Rx}}{2} ) .$$

ε_{Rx} denotes a mismatch of an amplitude in the receiver 517 and θ_{Rx} denotes a mismatch of a phase in the receiver 517.

When both the TX 513 and the RX 517 are calibrated, the procedure is performed by the TX 513, the loopback 515, and the RX 517. When only the TX 513 is calibrated, the procedure is performed by the TX 513, OTA, the spectrum analyzer, or the oscilloscope. When only the RX 517 is calibrated, the procedure is performed by the signal generator, OTA, and the RX 517.

Equation (3) and Equation (4) below corresponding to functions of the transmission signal and mismatch parameters are induced from the reception signal r.

$${I}^{out} = G [ {x}_{I} ( 1 + \frac{{ɛ}_{Tx}}{2} ) \cdot cos ( 2 π {f}_{c} t + \frac{{θ}_{Tx}}{2} + φ ) - {x}_{Q} ( 1 - \frac{{ɛ}_{Tx}}{2} ) \cdot sin ( 2 π {f}_{c} t - \frac{{θ}_{Tx}}{2} + φ ) ] ( 1 + \frac{{ɛ}_{Rx}}{2} ) cos ( 2 π {f}_{c} t + \frac{{θ}_{Rx}}{2} ) \qquad Equation ( 3 )$$

$${Q}^{out} = G [ {x}_{I} ( 1 + \frac{{ɛ}_{Tx}}{2} ) \cdot cos ( 2 π {f}_{c} t + \frac{{θ}_{Tx}}{2} + φ ) - {x}_{Q} ( 1 - \frac{{ɛ}_{Tx}}{2} ) \cdot sin ( 2 π {f}_{c} t - \frac{{θ}_{Tx}}{2} + φ ) ] ( 1 - \frac{{ɛ}_{Rx}}{2} ) ( - sin ( 2 π {f}_{c} t - \frac{{θ}_{Rx}}{2} ) ) \qquad Equation ( 4 )$$

G denotes a system gain.

Signals I^{out} and Q^{out}, after passing through the LPF 507 and the LPF 511, may be expressed by Equation (5) and Equation (6) below.

$$\begin{matrix}{I}^{out} = G ( 1 + \frac{{ɛ}_{Rx}}{2} ) [ {x}_{I} ( 1 + \frac{{ɛ}_{Tx}}{2} ) cos ( \frac{{θ}_{Tx} - {θ}_{Rx}}{2} + φ ) + {x}_{Q} ( 1 - \frac{{ɛ}_{Tx}}{2} ) sin ( \frac{{θ}_{Tx} + {θ}_{Rx}}{2} - φ ) ] + {DC}_{I} & Equation ( 5 ) \\ {Q}^{out} = G ( 1 - \frac{{ɛ}_{Rx}}{2} ) [ {x}_{I} ( 1 + \frac{{ɛ}_{Tx}}{2} ) sin ( \frac{{θ}_{Tx} + {θ}_{Rx}}{2} + φ ) + {x}_{Q} ( 1 - \frac{{ɛ}_{Tx}}{2} ) cos ( \frac{- {θ}_{Tx} + {θ}_{Rx}}{2} + φ ) ] + {DC}_{Q} & Equation ( 6 )\end{matrix}$$

For the reception signal r, r=I^{out}+jQ^{out}.

That is, the reception signal r may be expressed by a function of a loopback angle ϕ. Accordingly, in order to acquire the four mismatch parameters ε_{Tx}, ε_{Rx}, θ_{Tx}, and θ_{Rx}, estimating the loopback angle ϕ is required.

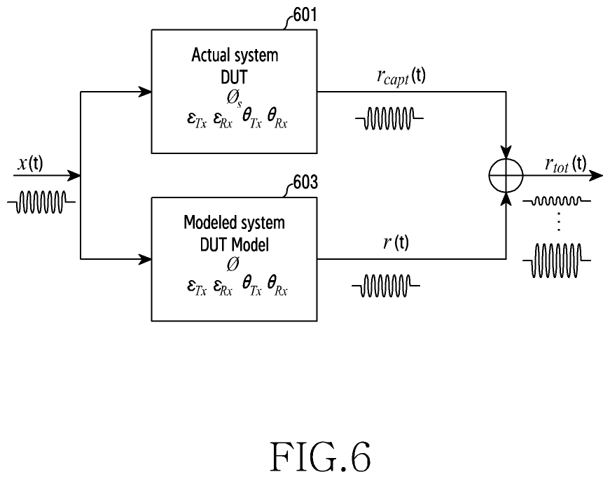

FIG. 6 illustrates a system for estimating a loopback angle for calibrating an I/Q mismatch according to an embodiment.

Referring to FIG. 6, for a transmission signal x(t) corresponding to x=x_{I}+jx_{Q}, a reception signal r_{capt}(t) captured from an actual system 601 may be acquired. For the transmission signal x(t), a reception signal r(t) expected by a modeled system 603 may be calculated and acquired.

r(t) is expressed by

$$r = G ( 1 + \frac{{ɛ}_{Rx}}{2} ) [ {x}_{I} ( 1 + \frac{{ɛ}_{Tx}}{2} ) cos ( \frac{{θ}_{Tx} - {θ}_{Rx}}{2} + φ ) + {x}_{Q} ( 1 - \frac{{ɛ}_{Tx}}{2} ) sin ( \frac{{θ}_{Tx} + {θ}_{Rx}}{2} - φ ) ] + jG ( 1 - \frac{{ɛ}_{Rx}}{2} ) [ {x}_{I} ( 1 + \frac{{ɛ}_{Tx}}{2} ) sin ( \frac{{θ}_{Tx} + {θ}_{Rx}}{2} + φ ) + {x}_{Q} ( 1 - \frac{{ɛ}_{Tx}}{2} ) cos ( \frac{- {θ}_{Tx} + {θ}_{Rx}}{2} + φ ) ]$$

for the transmission signal x(t) as described above.

Accordingly, rₜₒₜ(t) which is a sum of r_{capt}(t) and r(t) may be acquired as shown in Equation (7) below.

rₜₒₜ=r_{capt}+r Equation (7)

In Equation (7) above, r_{capt}(t) denotes a reception signal captured from the actual system 601, r(t) denotes a reception signal r(t) expected by the modeled system 603, and rₜₒₜ(t) denotes a sum of r_{capt}(t) and r(t).

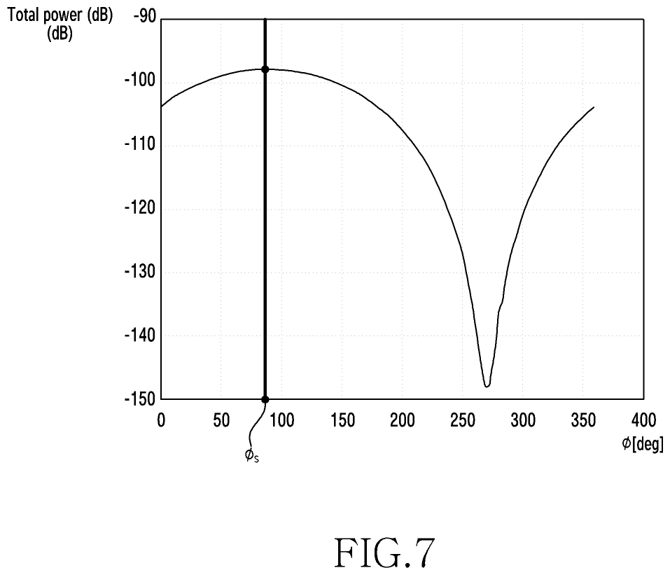

After tot is acquired from Equation (7) above, a loopback angle ϕₛ may be acquired from a graph of tot of FIG. 7 described below.

FIG. 7 illustrates a sum of I/Q power for estimating a loopback angle to calibrate an I/Q mismatch according to an embodiment.

Referring to FIG. 7, the x axis indicates ϕ[deg] and the y axis indicates total power [dB]. The total power [dB] may be expressed by total power=10 log|rₜₒₜ|².

The loopback angle ϕₛ may be expressed by

$${φ}_{s} = {arg}_{φ ∈ [ 0 , 2 π ]} max ( 10 log {\vert {r}_{tot} \vert}^{2} ) .$$

That is, as total power of the two signals r_{capt} and r has the same phase, the loopback angle ϕₛ corresponds to a phase that maximizes the total power [dB].

r(t) is expressed by

$$r = G ( 1 + \frac{{ɛ}_{Rx}}{2} ) [ {x}_{I} ( 1 + \frac{{ɛ}_{Tx}}{2} ) cos ( \frac{{θ}_{Tx} - {θ}_{Rx}}{2} + φ ) + {x}_{Q} ( 1 - \frac{{ɛ}_{Tx}}{2} ) sin ( \frac{{θ}_{Tx} + {θ}_{Rx}}{2} - φ ) ] + jG ( 1 - \frac{{ɛ}_{Rx}}{2} ) [ {x}_{I} ( 1 + \frac{{ɛ}_{Tx}}{2} ) sin ( \frac{{θ}_{Tx} + {θ}_{Rx}}{2} + φ ) + {x}_{Q} ( 1 - \frac{{ɛ}_{Tx}}{2} ) cos ( \frac{- {θ}_{Tx} + {θ}_{Rx}}{2} + φ ) ]$$

for the transmission signal x(t) as described above. That is, r(t) includes five parameters ϕ, ε_{Tx}, ε_{Rx}, θ_{Tx}, and θ_{Rx}.

Accordingly, searching for parameter values by adjusting all of the five parameters ϕ, ε_{Tx}, ε_{Rx}, θ_{Tx}, and θ_{Rx} to be maximum power in the modeled reception signal r in order to search for the loopback angle has too many numbers of cases, theoretically, and, thus, it takes a lot of time. Realistically, applying it is difficult.

However, values of the I/Q mismatch parameters ε_{Tx}, ε_{Rx}, θ_{Tx}, and θ_{Rx} are small, and a contribution to a change in the total power of the I/Q mismatch parameters ε_{Tx}, ε_{Rx}, θ_{Tx}, and θ_{Rx} is so small as to be negligible. Accordingly, it may be assumed that the I/Q mismatch parameters ε_{Tx}, ε_{Rx}, θ_{Tx}, and θ_{Rx} are 0 in order to simplify the modeled reception signal r in an embodiment of the present disclosure. According to an embodiment of the present disclosure, the I/Q mismatch parameters ε_{Tx}, ε_{Rx}, θ_{Tx}, and θ_{Rx} may be assumed to be predetermined values. The predetermined values may be average values of premeasured samples.

When the I/Q mismatch parameters ε_{Tx}, ε_{Rx}, θ_{Tx}, and θ_{Rx} are assumed to be 0, r(t), which was expressed by

$$r = G ( 1 + \frac{{ɛ}_{Rx}}{2} ) [ {x}_{I} ( 1 + \frac{{ɛ}_{Tx}}{2} ) cos ( \frac{{θ}_{Tx} - {θ}_{Rx}}{2} + φ ) + {x}_{Q} ( 1 - \frac{{ɛ}_{Tx}}{2} ) sin ( \frac{{θ}_{Tx} + {θ}_{Rx}}{2} - φ ) ] + jG ( 1 - \frac{{ɛ}_{Rx}}{2} ) [ {x}_{I} ( 1 + \frac{{ɛ}_{Tx}}{2} ) sin ( \frac{{θ}_{Tx} + {θ}_{Rx}}{2} + φ ) + {x}_{Q} ( 1 - \frac{{ɛ}_{Tx}}{2} ) cos ( \frac{- {θ}_{Tx} + {θ}_{Rx}}{2} + φ ) ]$$

for the transmission signal x(t) as described above, may be simplified by rₜᵤₙₑ as shown in Equation (8) below.

rₜᵤₙₑ=G(x_{I} cos ϕ−x_{Q} sin ϕ)+jG(x_{I} sin ϕ+x₀ cos ϕ) Equation (8)

The loopback angle ϕₛ may be expressed by

$${φ}_{s} = {arg}_{φ ∈ [ 0 , 2 π ]} max ( 10 log {\vert {r}_{tot} \vert}^{2} ) .$$

Accordingly, through simplification of the modeled reception signal r based on Equation (8) above, the search for the loopback angle ϕₛ may be simplified from a five-dimensional arrangement search for the five conventional parameters ϕ, ε_{Tx}, ε_{Rx}, θ_{Tx}, and θ_{Rx} to a one-dimensional arrangement search for the one parameter ϕ.

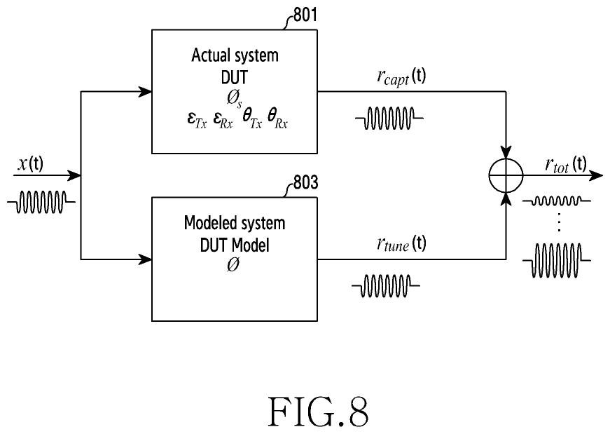

FIG. 8 illustrates a system for normalizing a signal in order to estimate a loopback angle for calibrating an I/Q mismatch according to an embodiment.

Referring to FIG. 8, a structure of a system is illustrated in which the search for the loopback angle ϕₛ is simplified to the one-dimensional arrangement search for the one parameter ϕ through simplification of Equation (8) above.

In the search for the loopback angle ϕₛ, normalizing the signal in order to remove the influence of the amplitude difference is required. The reception signal r_{capt}(t) captured from the actual system 801 and the reception signal rₜᵤₙₑ modeled through Equation (8) above by the modeled system 803 may be normalized and, accordingly, a total signal rₜₒₜ may be expressed as Equation (9) below.

$${r}_{tot} = \frac{{r}_{tune}}{max ( \vert {r}_{tune} \vert )} + \frac{{r}_{cap}}{max ( \vert {r}_{cap} \vert )} \qquad Equation ( 9 )$$

In Equation (9) above, rₜᵤₙₑ denotes a reception signal modeled through Equation (8) above by the modeled system 803, r_{capt} is a reception signal captured from the actual system 801, and rₜₒₜ is a sum of the normalized rₜᵤₙₑ and the normalized r_{capt}.

The search for the loopback angle ϕs may be simplified and expressed by Equation (10) below.

$${φ}_{s} = {arg}_{φ ∈ [ 0 , 2 π ]} max ( 10 log {\vert {r}_{tot} \vert}^{2} ) \qquad Equation ( 10 )$$

In Equation (10) above, rₜₒₜ denotes a sum of normalized rₜᵤₙₑ and normalized r_{cap}, and ϕₛ denotes a loopback angle.

When the loopback angle ϕₛ is determined, four equations may be formulated for four unknown parameters ε_{Tx}, ε_{Rx}, θ_{Tx}, and θ_{Tx}.

A general method is evaluating a second-order characteristic of an output signal which may be generalized to a function of I/Q mismatch parameters.

Normalized power R of the reception signal may be expressed by Equation (11) below.

$$R = \frac{E [ {( r - DC )}^{2} ]}{E [ {\vert ( r - DC ) \vert}^{2} ]} \qquad Equation ( 11 )$$

In Equation (11) above, R denotes normalized power and E[X] denotes an expected value (mean) of X.

In Equation (11) above, r−DC=I^{out}+jQ^{out}. Here,

$${I}^{out} ≅ G [ ( 1 + \frac{{ɛ}_{Tx} + {ɛ}_{Rx}}{2} ) ( cos φ + \frac{{θ}_{Tx} + {θ}_{Rx}}{2} sin φ ) {x}_{I} + ( 1 - \frac{{ɛ}_{Tx} - {ɛ}_{Rx}}{2} ) ( sin φ + \frac{{θ}_{Tx} + {θ}_{Rx}}{2} cos φ ) {x}_{Q} ]$$

$${Q}^{out} ≅ G [ ( 1 + \frac{{ɛ}_{Tx} - {ɛ}_{Rx}}{2} ) ( - sin φ + \frac{{θ}_{Tx} + {θ}_{Rx}}{2} cos φ ) {x}_{I} + ( 1 - \frac{{ɛ}_{Tx} + {ɛ}_{Rx}}{2} ) ( cos φ - \frac{{θ}_{Tx} - {θ}_{Rx}}{2} sin φ ) {x}_{Q} ]$$

and this may be simplified to I^{out}=G[(1+x₁)(cos ϕ+y₁ sin ϕ)x_{I}+(1−x₂)(sin ϕ+y₂ cos ϕ)x_{Q}] Q^{out}=G[(1+x₂)(−sin ϕ+y₂ cos ϕ)x_{I}+(1−x₁)(cos ϕ−y₁ sin ϕ)x_{Q}]. Here,

$${x}_{1} = \frac{{ɛ}_{Tx} + {ɛ}_{Rx}}{2} , {x}_{2} = \frac{{ɛ}_{Tx} - {ɛ}_{Rx}}{2} , {y}_{1} = \frac{{θ}_{Tx} - {θ}_{Rx}}{2} , and {y}_{2} = \frac{{θ}_{Tx} + {θ}_{Rx}}{2} . \\ {I}^{out} ≅ G [ ( 1 + \frac{{ɛ}_{Tx} + {ɛ}_{Rx}}{2} ) ( cos φ + \frac{{θ}_{Tx} - {θ}_{Rx}}{2} sin φ ) {x}_{I} + ( 1 - \frac{{ɛ}_{Tx} - {ɛ}_{Rx}}{2} ) ( sin φ + \frac{{θ}_{Tx} + {θ}_{Rx}}{2} cos φ ) {x}_{Q} ]$$

$${Q}^{out} ≅ G [ ( 1 + \frac{{ɛ}_{Tx} - {ɛ}_{Rx}}{2} ) ( - sin φ + \frac{{θ}_{Tx} + {θ}_{Rx}}{2} cos φ ) {x}_{I} + ( 1 - \frac{{ɛ}_{Tx} + {ɛ}_{Rx}}{2} ) ( cos φ - \frac{{θ}_{Tx} - {θ}_{Rx}}{2} sin φ ) {x}_{Q} ]$$

may be expressed by I^{out}=G[a₁x_{I}+a₂x_{Q}], Q^{out}=G[b₁x_{I}+b₂x_{Q}]. Here, a₁=(1+x₁)(cos ϕ+y₁ sin ϕ), a₂=(1−x₂)(sin ϕ+y₂ cos ϕ), b₁=(1+x₂)(−sin ϕ+y₂ cos ϕ), and b₂=(1−x₁)(cos ϕ−y₁ sin ϕ).

When a predetermined signal that meets E[x_{I}x_{Q}]=0 and E[x_{I}²]=E[x_{Q}²] and E[x_{I}²]=E[x_{Q}²] is assumed for I^{out}=G[a₁x_{I}+a₂x_{Q}], Q^{out}=G[b₁x_{I}+b₂x_{Q}], the normalized power R of the reception signal may be simplified as follows.

$$R = \frac{E [ {( r - DC )}^{2} ]}{E [ {\vert ( r - DC ) \vert}^{2} ]} = \frac{{a}_{1}^{2} + {a}_{2}^{2} - {b}_{1}^{2} - {b}_{2}^{2}}{{a}_{1}^{2} + {a}_{2}^{2} + {b}_{1}^{2} + {b}_{2}^{2}} + j \frac{2 {a}_{1} {b}_{1} + 2 {a}_{2} {b}_{2}}{{a}_{1}^{2} + {a}_{2}^{2} + {b}_{1}^{2} + {b}_{2}^{2}} ,$$

that is, the normalized power R of the reception signal may be expressed by Equation (12) below.

R=Re{R}+jIm{R} Equation (12)

In Equation (12) above, R denotes normalized power, Re {R} denotes a real number part of R, and Im{R} denotes an imaginary number part of R.

In the case of |xᵢ|,|yⱼ|<<1, xᵢ²→0, xⱼ²→0, and xᵢyⱼ→0. Accordingly, the normalized power R of the reception signal may be converted to the following linear equations.

Re{R}=f₁₁x₁+f₁₂x₂+f₁₃y₁+f₁₄y₂

Im{R}=f₂₁x₁+f₂₂x₂+f₂₃y₁+f₂₄y₂

Here, f₁₁=2 cos² ϕ, f₁₂=2 sin² ϕ, f₁₃=2 cos ϕ sin ϕ, f₁₄=2 cos ϕ sin ϕ, f₂₁=−2 cos ϕ sin ϕ, f₂₂=−2 cos ϕ sin ϕ, f₂₃=−2 sin² ϕ, and f₂₄=2 cos² ϕ.

The real number part and the imaginary number part of the normalized power R of the reception signal may be expressed by Equation (13) and Equation (14) below.

f(ε_{Tx},ε_{Rx},θ_{Tx},θ_{Rx})=Re{R} Equation (13)

g(ε_{Tx},ε_{Rx},θ_{Tx},θ_{Rx})=Im{R} Equation (14)

R denotes normalized power, and ε_{Tx}, ε_{Rx}, θ_{Tx}, and θ_{Rx} denote I/Q mismatch parameters.

For the four unknown parameters ε_{Tx}, ε_{Rx}, θ_{Tx}, and θ_{Rx}, four equations may be formulated. Since there are four unknown parameters, four equations are needed. A method of acquiring four equations is acquiring signals having two different values of the loopback angle.

That is, from two loopback angles ϕ₁ and ϕ₂, four equations corresponding to Equation (15) to Equation (18) below may be acquired for the four unknown parameters ε_{Tx}, ε_{Rx}, θ_{Tx}, and θ_{Rx}. Specifically, Equation (15) and Equation (16) below may be acquired from the first loopback angle ϕ₁ and Equation (17) and Equation (18) below may be acquired from the second loopback angle ϕ₂.

f₁(ε_{Tx},ε_{Rx},θ_{Tx},θ_{Rx})=Re{R₁} Equation (15)

f₂(ε_{Tx},ε_{Rx},θ_{Tx},θ_{Rx})=Im{R₁} Equation(16)

f₃(ε_{Tx},ε_{Rx},θ_{Tx},θ_{Rx})=Re{R₂} Equation (17)

f₄(ε_{Tx},ϵ_{Rx},θ_{Tx},θ_{Rx})={R₂} Equation (18)

ε_{Tx}, ε_{Rx}, θ_{Tx}, and θ_{Rx} are I/Q mismatch parameters. R₁ denotes normalized first power of a signal received from the first loopback angle ϕ₁ through a first loopback path. R₂ denotes normalized second power of a signal received from the second loopback angle ϕ₂ through a second loopback path.

Equation (15) to Equation (18) above may be expressed as follows.

Re{R₁}=f₁₁x₁+f₁₂x₂+f₁₃y₁+f₁₄y₂

Im{R₁}=f₂₁x₁+f₂₂x₂+f₂₃y₁+f₂₄y₂

Re{R₂}=f₃₁x₁+f₃₂x₂+f₃₃y₁+f₃₄y₂

Im{R₂}=f₄₁x₁+f₄₂x₂+f₄₃y₁+f₄₄y₂

Here,

$${x}_{1} = \frac{{ɛ}_{Tx} + {ɛ}_{Rx}}{2} , {x}_{2} = \frac{{ɛ}_{Tx} - {ɛ}_{Rx}}{2} , {y}_{1} = \frac{{θ}_{Tx} - {θ}_{Rx}}{2} , and {y}_{2} = \frac{{θ}_{Tx} + {θ}_{Rx}}{2} .$$

Further, f₁₁=2 cos² ϕ₁, f₁₂=−2 sin² ϕ1, f₁₃=2 cos ϕ1 sin ϕ1, f₁₄=2 cos ϕ1 sin ϕ1, f₂₁=−2 cos ϕ1 sin ϕ1, f₂₂=−2 cos ϕ1 sin ϕ1, f₂₃=2 sin² ϕ1, f₂₄=2 cos² ϕ1, f₃₁=2 cos² ϕ2, f₃₂=−2 sin² ϕ2, f₃₃=2 cos ϕ2 sin ϕ2, f₃₄=2 cos ϕ2 sin ϕ2, f₄₁=−2 cos ϕ2 sin ϕ2, f₄₂=−2 cos ϕ2 sin ϕ2, f₄₃=−2 sin² ϕ2, and f₄₄=2 cos² ϕ2.

The coefficients f₁₁ to f₄₄ may be expressed by one matrix shown in Equation (19) below.

$$F = [ \begin{matrix}{f}_{11} & {f}_{12} & {f}_{13} & {f}_{14} \\ {f}_{21} & {f}_{21} & {f}_{23} & {f}_{24} \\ {f}_{31} & {f}_{32} & {f}_{33} & {f}_{34} \\ {f}_{41} & {f}_{42} & {f}_{43} & {f}_{44}\end{matrix} ] \qquad Equation ( 19 )$$

In Equation (19) above, f₁₁=2 cos² ϕ₁, f₁₂=−2 sin² ϕ₁; f₁₃=2 cos ϕ1 sin ϕ1, f₁₄=2 cos ϕ₁ sin ϕ₁, f₂₁=−2 cos ϕ₁ sin ϕ₁, f₂₂=−2 cos ϕ₁ sin ϕ₁, f₂₃=−2 sin² ϕ₁, f₂₄=2 cos² ϕ₁, f₃₁=2 cos² ϕ₂, f₃₂=−2 sin² ϕ₂, f₃₃=2 cos ϕ₂ sin ϕ₂, f₃₄=2 cos ϕ₂ sin ϕ₂, f₄₁=−2 cos ϕ₂ sin ϕ₂, f₄₂=−2 cos ϕ₂ sin ϕ₂, f₄₃=−2 sin² ϕ₂, and f₄₄=2 cos² ϕ₂.

$$P = [ \begin{matrix}{p}_{11} \\ {p}_{21} \\ {p}_{31} \\ {p}_{41}\end{matrix} ] ,$$

where p₁₁=Re{R₁}, p₂₁=Im{R₁}, p₃₁=Re{R₂}, and p₄₁=Im{R₂}.

$$z = [ \begin{matrix}{z}_{11} \\ {z}_{21} \\ {z}_{31} \\ {z}_{41}\end{matrix} ] ,$$

where z₁₁=x₁, z₂₁=x₂, z₃₁=y₁, and z₄₁=y₂, F, P, and z have the relation shown in Equation (20) below.

F·z=P Equation (20)

By solving Equation (20) above, which is the linear equation for Z, solutions in Equation (21) below may be acquired for the four unknown parameters ε_{Tx}, ε_{Rx}, θ_{Tx}, and θ_{Rx}.

$${ɛ}_{Tx} = \frac{{z}_{11} + {z}_{21}}{2} {θ}_{Tx} = \frac{{z}_{31} + {z}_{41}}{2} \\ {ɛ}_{Rx} = \frac{{z}_{11} - {z}_{21}}{2} {θ}_{Rx} = \frac{- {z}_{31} + {z}_{41}}{2} \qquad Equation ( 21 )$$

According to an embodiment of the present disclosure, it is possible to easily acquire I/Q mismatch parameters within a short period of time through a simple operation.

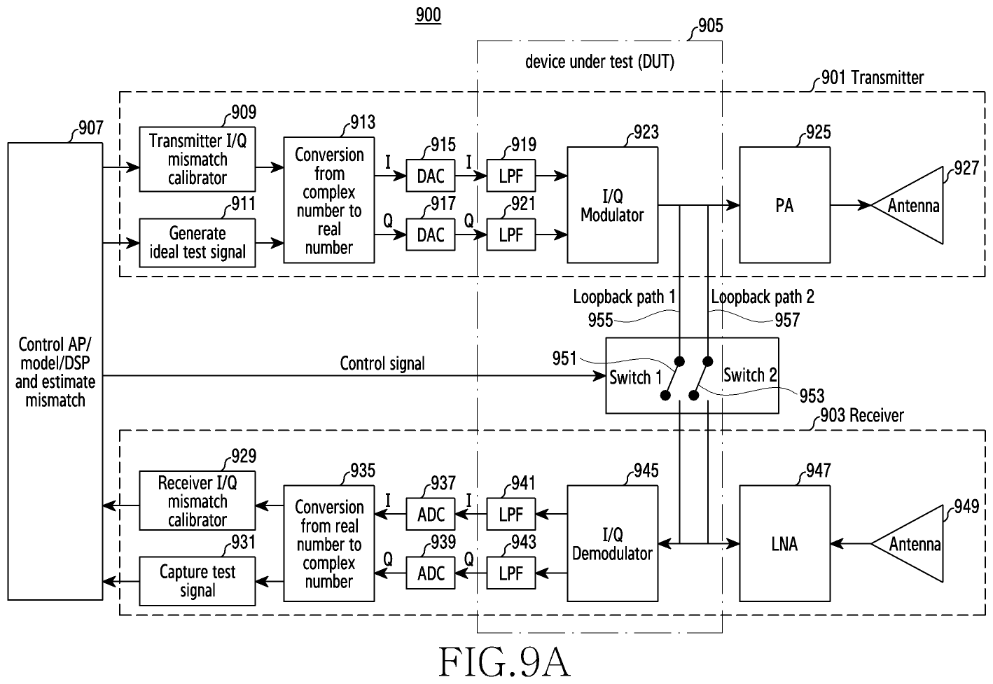

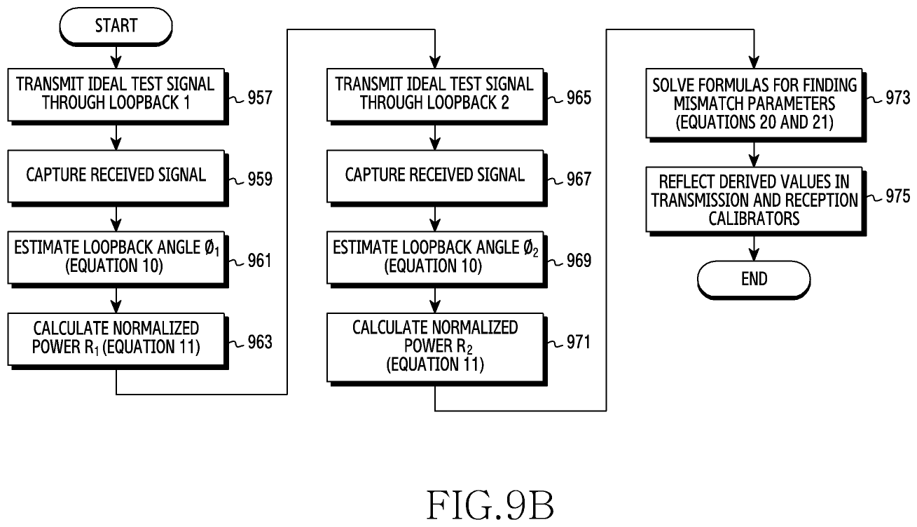

FIG. 9A illustrates a device for calibrating I/Q mismatches of a transmitter and a receiver according to an embodiment.

Referring to FIG. 9A, the electronic device 900 includes the transmitter 901, the receiver 903, and at least one processor 907. The electronic device 900 may calibrate I/Q mismatches for both the transmitter 901 and the receiver 903.

At least one processor 907 may be operatively connected to the transmitter 901 and the receiver 903 and may control the transmitter 901 and the receiver 903. Specifically, at least one processor 907 may function as an application processor (AP) or a modem and may perform digital signal processing (DSP) control and I/Q mismatch estimation.

After generating an ideal test signal as indicated by reference numeral 911, the transmitter 901 converts the ideal test signal from a complex number to a real number as indicated by reference numeral 913, and allows the test signal to pass through digital-to-analog (DAC) converter 915 and DAC 917 through an I branch and a Q branch, respectively. The transmitter 901 allows the test signal of I and Q to pass through LPF 919 and LPF 921, respectively, and then inputs into an I/Q modulator 923. The signals passing through the I/Q modulator 923 pass through a PA 925 and then are transmitted through an antenna 927.

The receiver 903 allows the signal received through the antenna 949 to pass through an LNA 947 and then inputs into an I/Q demodulator 945. The signal of I and Q passing through the I/Q demodulator 945 passes through LPF 941 and LPF 943 and then passes through analog-to-digital converter (ADC) 937 and ADC 939. The receiver 903 converts the signal passing through the ADC 937 and the ADC 939 from a real number to a complex number as indicated by reference 935 and captures a test signal as indicated by reference numeral 931.

The transmitter 901 and the receiver 903 include a device under test (DUT) 905 for determining I/Q mismatch parameters. The DUT 905 includes a first loopback path 955 and a second loopback path 957. A first switch 951 and a second switch 953 connect the first loopback path 955 and the second loopback path 957 based on a control signal from at least one processor 907.

At least one processor 907 may acquire two loopback angles ϕ₁ and ϕ₂ from the first loopback path 955 and the second loopback path 957 for the I/Q mismatch parameters. At least one processor 907 determines four unknown parameters ε_{Tx}, ε_{Rx}, θ_{Tx}, and θ_{Rx} which are I/Q mismatch parameters from the two loopback angles ϕ₁ and ϕ₂. At least one processor 907 determines whether there are I/Q mismatches of the transmitter 901 and the receiver 903 and how much the I/Q mismatches are calibrated based on the determined I/Q mismatch parameters ε_{Tx}, ε_{Rx}, θ_{Tx}, and θ_{Rx}. At least one processor 907 transmits a calibration signal and calibrates the I/Q mismatch of the transmitter 901 by controlling a transmitter I/Q mismatch calibrator 909. At least one processor 907 receives a calibration signal and calibrates the I/Q mismatch of the receiver 903 by controlling a receiver I/Q mismatch calibrator 929.

One device determines the I/Q mismatch and calibrates the I/Q mismatch. However, according to an embodiment of the present disclosure, within a device to be calibrated for the I/Q mismatch, a signal having undergone modulation, passing through the intermediate path between the transmitter and the receiver, and having undergone demodulation may also be transmitted and thus determination of the I/Q mismatch may be performed by an external device.

FIG. 9B is a flowchart of a method of calibrating I/Q mismatches of a transmitter and a receiver according to an embodiment.

Referring to FIG. 9B, in step 957, an electronic device transmits an ideal test signal through a first loopback path. The first loopback path is a path connecting a node before a power amplifier after I/Q modulation in a transmitter within the electronic device and a node before I/Q demodulation after a low noise amplifier in a receiver within the electronic device. The first loopback path is connected by a first switch operated by a control signal of at least one processor within the electronic device. An ideal test signal is transmitted through the first loopback path after undergoing I/Q modulation of the transmitter. Accordingly, when the ideal test signal reaches the first loopback path, the I/Q mismatch of the transmitter within the electronic device has been reflected in the ideal test signal.

In step 959, the electronic device captures a reception signal. The reception signal is a signal received by the receiver within the electronic device after the ideal test signal passes through I/Q modulation of the transmitter, passes through the first loopback path, and then passes through I/Q demodulation of the receiver within the electronic device. Accordingly, when the reception signal is captured, the I/Q mismatch of the receiver within the electronic device has been reflected in the reception signal.

In step 961, the electronic device estimates a first loopback angle. A detailed method of estimating the first loopback angle is as shown in Equation (10) described above. That is, the first loopback angle may be an angle that maximizes a sum of power of the reception signal captured in step 959 and the reception signal predicted by the modeled system. According to an embodiment, it may be assumed that I/Q mismatch parameters ε_{Tx}, ε_{Rx}, θ_{Tx}, and θ_{Rx} are 0 for the reception signal predicted by the modeled system. Alternatively, it may be assumed that PQ mismatch parameters ε_{Tx}, ε_{Rx}, θ_{Tx}, and θ_{Rx} are predetermined values for the reception signal predicted by the modeled system. The predetermined values may be average values of premeasured samples.

In step 963, the electronic device calculates normalized first power of the reception signal. A detailed method of calculating first power is as shown in Equation (11) described above. The normalized first power may be simplified in the form of a complex number having a real number part and an imaginary number part.

In step 965, the electronic device transmits an ideal test signal through a second loopback path. The second loopback path is a path connecting two nodes which are the same as those of the first loopback and connected to the first loopback path in parallel. The second loopback path is connected by a second switch operated by a control signal of at least one processor within the electronic device. An ideal test signal is transmitted through the second loopback path after undergoing I/Q modulation of the transmitter. Accordingly, when the ideal test signal reaches the second loopback path, the I/Q mismatch of the transmitter within the electronic device is reflected in the ideal test signal.

In step 967, the electronic device captures a reception signal. The reception signal is a signal received by the receiver within the electronic device after the ideal test signal passes through I/Q modulation of the transmitter, passes through the second loopback path, and then passes through I/Q demodulation of the receiver within the electronic device. Accordingly, when the reception signal is captured, the I/Q mismatch of the receiver within the electronic device has been reflected in the reception signal.

In step 969, the electronic device estimates a second loopback angle. A detailed method of estimating the second loopback angle is as shown in Equation (10) described above. That is, the second loopback angle may be an angle that maximizes a sum of power of the reception signal captured in step 967 and the reception signal predicted by the modeled system. According to an embodiment, it may be assumed that I/Q mismatch parameters ε_{Tx}, ε_{Rx}, θ_{Tx}, and θ_{Rx} are 0 for the reception signal predicted by the modeled system. Alternatively, it may be assumed that I/Q mismatch parameters ε_{Tx}, ε_{Rx}, θ_{Tx}, and θ_{Rx} are predetermined values for the reception signal predicted by the modeled system. The predetermined values may be average values of premeasured samples.

In step 971, the electronic device calculates normalized second power. A detailed method of calculating second power is as shown in Equation (11) described above. The normalized second power may be simplified in the form of a complex number having a real number part and an imaginary number part.

In step 973, the electronic device calculates I/Q parameters based on the normalized first power and the normalized second power. A detailed method of calculating I/Q parameters may be as shown in Equation (20) and Equation (21) described above. That is, the electronic device acquires four equations for four I/Q mismatch parameters ε_{Tx}, ε_{Rx}, θ_{Tx}, and θ_{Rx} from the normalized first power and the normalized second power. The electronic device calculates the four I/Q mismatch parameters ε_{Tx}, ε_{Rx}, θ_{Tx}, and θ_{Rx} by solving the four equations.

In step 975, the electronic device calibrates I/Q mismatches of the transmitter and the receiver by controlling a transmission calibrator and a reception calibrator based on the I/Q parameters. At least one processor within the electronic device may control the transmission calibrator to transmit the signal for which the I/Q mismatch has been calibrated and control the reception calibrator to receive the signal for which the I/Q mismatch has been calibrated.

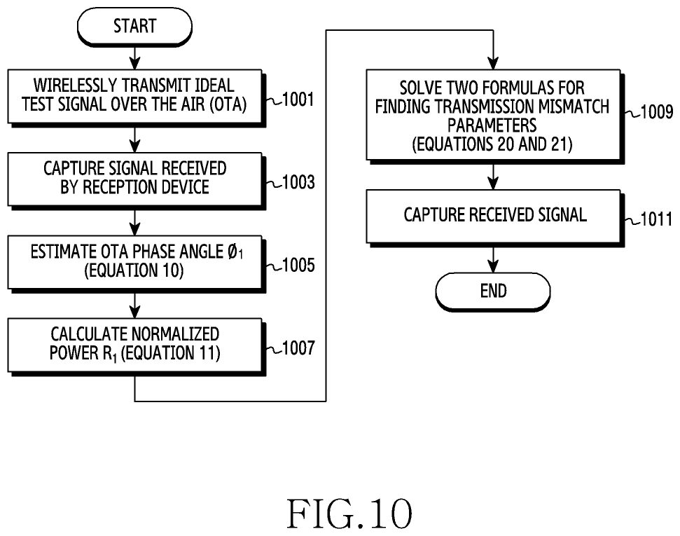

FIG. 10 is a flowchart of a method of calibrating an I/Q mismatch of a transmitter according to an embodiment.

Referring to FIG. 10, in step 1001, the transmitter within the electronic device transmits an ideal test signal to a reception device or a receiver wirelessly, that is, OTA. The reception device receives the ideal test signal OTA. The reception device may be a spectrum analyzer or an oscilloscope. The ideal test signal is transmitted OTA after undergoing I/Q modulation of the transmitter. Accordingly, when the ideal test signal reaches the reception device, the I/Q mismatch of the transmitter within the electronic device has been reflected in the ideal test signal.

In step 1003, the reception device within the electronic device captures a reception signal. The reception signal is a signal received by the reception device within the electronic device after the ideal test signal passes through I/Q modulation of the transmitter within the electronic device, passes OTA, and then passes through I/Q demodulation of the reception device within the electronic device. However, since the reception device within the electronic device is a device for which the I/Q calibration has been performed, only the I/Q mismatch of the transmitter exists during the process of transmitting the signal without the generation of the I/Q mismatch during the process of receiving the signal. Accordingly, among the four I/Q mismatch parameters ε_{Tx}, ε_{Rx}, θ_{Tx}, and θ_{Rx}, the I/Q mismatch parameters ε_{Rx} and θ_{Rx} related to reception may be 0 and only the I/Q mismatch parameters ε_{Tx} and θ_{Tx} related to transmission have meaningful values.

In step 1005, the electronic device estimates an OTA phase angle. A detailed method of estimating the OTA phase angle may be as shown in Equation (10) described above. That is, the OTA phase angle may be an angle that maximizes a sum of power of the reception signal captured in step 1003 and the reception signal predicted by the modeled system. It may be assumed that I/Q mismatch parameters ε_{Tx}, ε_{Rx}, θ_{Tx}, and θ_{Rx} are 0 for the reception signal predicted by the modeled system.

In step 1007, the electronic device calculates normalized power of the reception signal. A detailed method of calculating normalized power may be as shown in Equation (11) described above. The normalized power may be simplified in the form of a complex number having a real number part and an imaginary number part.

In step 1009, the electronic device calculates I/Q parameters ε_{Tx} and θ_{Tx} based on the normalized power. Among the four I/Q mismatch parameters ε_{Tx}, ε_{Rx}, θ_{Tx}, and θ_{Rx}, the I/Q mismatch parameters ε_{Rx} and θ_{Rx} related to reception may be 0 and only the I/Q mismatch parameters ε_{Rx} and θ_{Tx} have meaningful values. A detailed method of calculating I/Q parameters may be as shown in Equation (20) and Equation (21) described above. That is, the electronic device acquires two equations for two I/Q mismatch parameters ε_{Tx} and θ_{Tx} from the normalized power. The electronic device calculates the two I/Q mismatch parameters ε_{Tx} and θ_{Tx} by solving the two equations.

In step 1011, the electronic device calibrates the I/Q mismatch of the transmitter by controlling a transmission calibrator based on the I/Q parameters ε_{Tx} and θ_{Tx}. At least one processor within the electronic device may control the transmission calibrator to transmit the signal for which the I/Q mismatch has been calibrated.

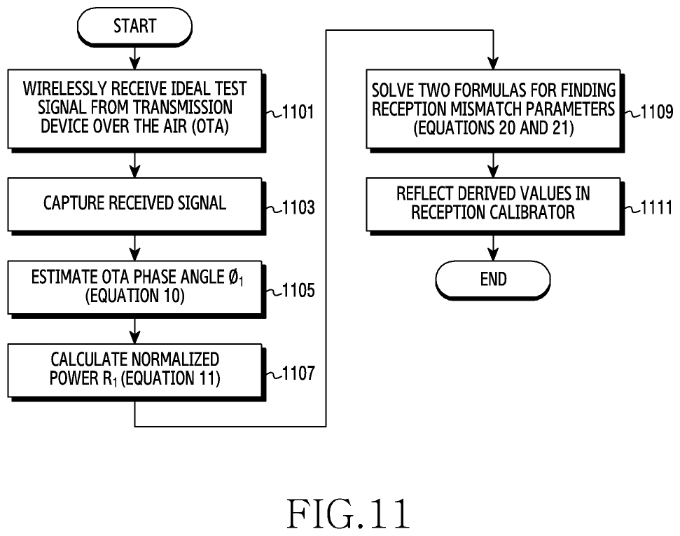

FIG. 11 is a flowchart of a method of calibrating an I/Q mismatch of a receiver according to an embodiment.

Referring to FIG. 11, in step 1101, a transmission device or a transmitter within the electronic device transmits an ideal test signal to a reception device wirelessly, that is, OTA. The receiver receives the ideal test signal OTA. The transmission device may be a signal generator. The ideal test signal is transmitted OTA after undergoing I/Q modulation of the transmitter. However, since the transmission device within the electronic device is a device for which the I/Q calibration has been already performed, only the I/Q mismatch of the receiver exists during the process of receiving the signal without generation of the I/Q mismatch during the process of transmitting the signal. Accordingly, among the four I/Q mismatch parameters θ_{Tx}, ε_{Rx}, θ_{Tx}, and θ_{Rx}, the I/Q mismatch parameters ε_{Tx} and θ_{Tx} related to transmission may be 0 and only the I/Q mismatch parameters ε_{Rx} and θ_{Rx} related to reception have meaningful values.

In step 1103, the receiver within the electronic device captures a reception signal. The reception signal is a signal received by the reception device within the electronic device after the ideal test signal undergoes I/Q modulation of the transmission device within the electronic device, passes OTA, and then undergoes I/Q demodulation of the receiver within the electronic device. Accordingly, when the reception signal is captured, the I/Q mismatch of the receiver within the electronic device has been reflected in the reception signal.

In step 1105, the electronic device estimates an OTA phase angle. A detailed method of estimating the OTA phase angle may be as shown in Equation (10) described above. That is, the OTA phase angle may be an angle that maximizes a sum of power of the reception signal captured in step 1103 and the reception signal predicted by the modeled system. It may be assumed that I/Q mismatch parameters ε_{Tx}, ε_{Rx}, θ_{Tx}, and θ_{Rx} are 0 for the reception signal predicted by the modeled system.

In step 1107, the electronic device calculates normalized power of the reception signal. A detailed method of calculating normalized power may be as shown in Equation (11) described above. The normalized power may be simplified in the form of a complex number having a real number part and an imaginary number part.

In step 1109, the electronic device calculates I/Q parameters ε_{Rx} and θ_{Rx} based on the normalized power; Among the four I/Q mismatch parameters ε_{Tx}, ε_{Rx}, θ_{Tx}, and θ_{Rx}, the I/Q mismatch parameters ε_{Tx} and θ_{Tx} related to transmission may be 0 and only the I/Q mismatch parameters ε_{Rx} and θ_{Rx} related to reception have meaningful values. A detailed method of calculating I/Q parameters may be as shown in Equation (20) and Equation (21) described above. That is, the electronic device acquires two equations for two I/Q mismatch parameters ε_{Rx} and θ_{Rx} from the normalized power. The electronic device calculates the two I/Q mismatch parameters ε_{Rx} and θ_{Rx} by solving the two equations.

In step 1111, the electronic device calibrates the I/Q mismatch of the receiver by controlling the reception calibrator based on the I/Q parameters ε_{Rx} and θ_{Rx}. At least one processor within the electronic device may control the reception calibrator to receive the signal for which the I/Q mismatch is calibrated.

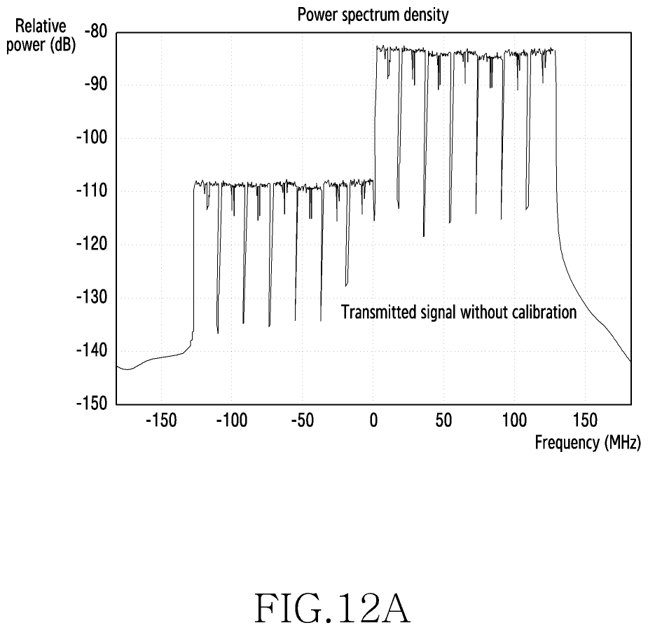

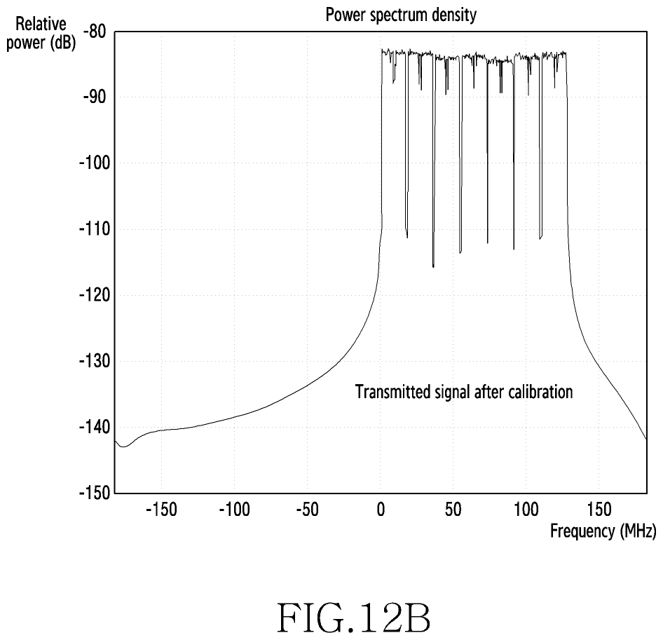

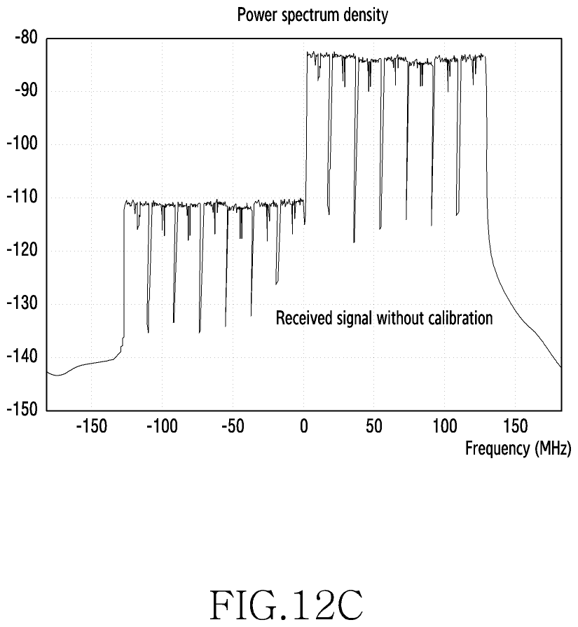

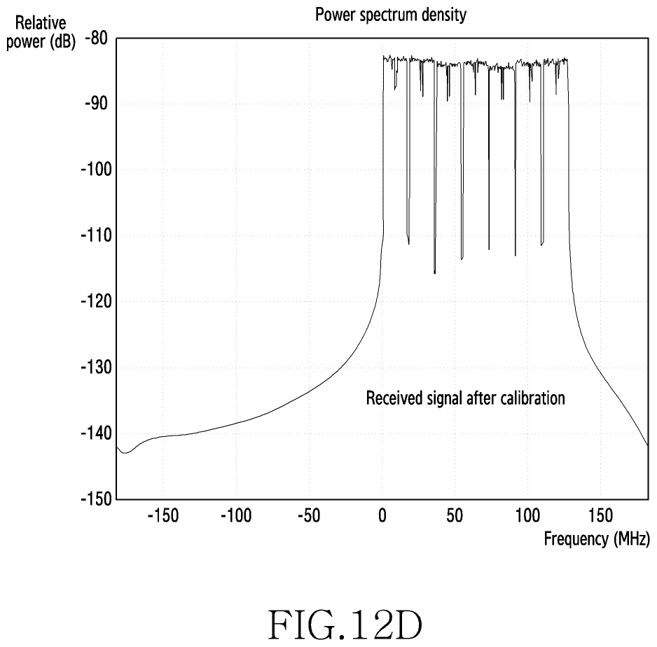

FIG. 12A illustrates a power spectrum density of a signal transmitted without any calibration for the I/Q mismatch according to an embodiment. Specifically, FIG. 12A illustrates a power spectrum density of a transmission signal when the I/Q mismatch is generated during a process of performing quadrature modulation when an original signal is transmitted.

FIG. 12A illustrates an I/Q mismatch being generated when ε_{Tx} and θ_{Tx} are not 0.

Referring to FIG. 12A, the transmission signal has relatively high power even in an image signal band due to the I/Q mismatch. Accordingly, an undesired image signal is transmitted.

FIG. 12B illustrates a power spectrum density of a signal transmitted after the I/Q mismatch is calibrated according to an embodiment.

Referring to FIG. 12B, the transmission signal has high power in an original signal band and has relatively low power in an image signal band. Accordingly, a desired signal is transmitted without any image signal.

FIG. 12C illustrates a power spectrum density of a signal received without calibration for the I/Q mismatch according to an embodiment. Specifically, FIG. 12C illustrates a power spectrum density of a reception signal when the I/Q mismatch is generated during a process of performing quadrature modulation when an original signal is received. FIG. 12C illustrates the case in which the I/Q mismatch is generated when ε_{Rx} and θ_{Rx} are not 0.

Referring to FIG. 12C, the reception signal has relatively high power even in the image signal band due to the I/Q mismatch. Accordingly, an undesired image signal is received.

FIG. 12D illustrates a power spectrum density of a signal received after the I/Q mismatch is calibrated according to an embodiment.

Referring to FIG. 12D, the reception signal has high power in an original signal band and has low power in an image signal band. Accordingly, a desired signal is received without any image signal.

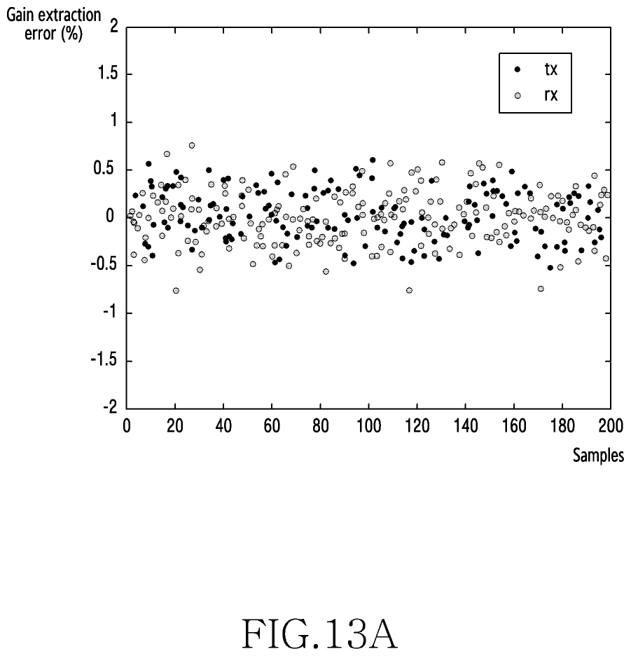

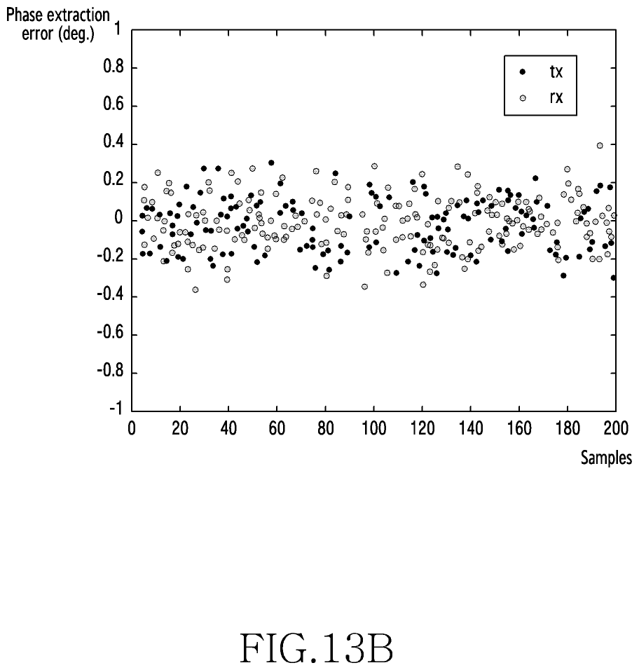

FIG. 13A illustrates gain extraction errors of a transmission signal and a reception signal after the I/Q mismatch is calibrated according to an embodiment. FIG. 13B illustrates phase extraction errors of a transmission signal and a reception signal after the I/Q mismatch is calibrated according to an embodiment.

Referring to FIGS. 13A and 13B, a simulation result is shown in FIG. 13A of a transceiver model by injecting 200 random samples of I/Q mismatch parameters in order to identify accuracy of the I/Q mismatch calibration method and FIG. 13B shows a simulation result of a transceiver model by injecting 200 random samples of I/Q mismatch parameters in order to identify accuracy of the I/Q mismatch calibration method. It is assumed that an actual signal-to-noise ratio (SNR) of a loopback path is 20 dB. An extraction error defined as a difference between the calculated error and the known actual error is observed from the simulation. That is, extraction error is equal to a calculated error minus a known error. Based on the simulation result, maximum values of gain error extraction and phase error extraction are about 0.75% and 0.4 degrees, respectively, according to the I/Q mismatch calibration method. Standard deviations (Std) of gain error extraction and phase error extraction are 0.27% and 0.15 degrees. Theoretically, an average EVM is −37.25 dB and a worst EVM is −36.7 dB. This indicates that the extracted error is ignorable or the calculation is accurate.

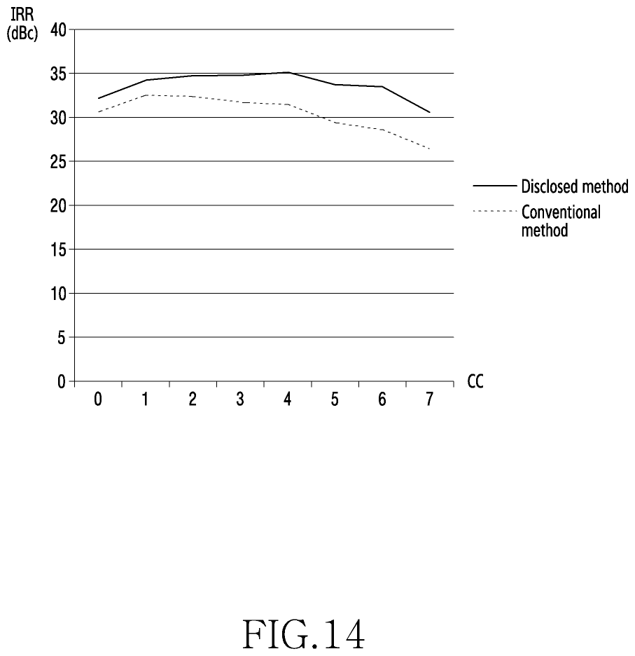

FIG. 14 illustrates IRRs of an I/Q mismatch calibration method according to an embodiment.

The accuracy of the I/Q mismatch calibration method of an embodiment of the disclosure has been identified by measurement.

Referring to FIG. 14, through IRRs of 8 component carriers (CCs) of a modulation signal, the measurement results of the I/Q mismatch calibration method of the embodiment of the disclosure and the conventional I/Q mismatch calibration method are compared. The I/Q mismatch calibration method of an embodiment of the disclosure has a higher performance than the conventional I/Q mismatch calibration method.

Methods according to embodiments of the disclosure may be implemented in hardware, software, or a combination of hardware and software.

When the methods are implemented in software, a non-transitory computer-readable storage medium for storing one or more programs (e.g., software modules) may be provided. The one or more programs stored in the non-transitory computer-readable storage medium may be configured for execution by one or more processors within the electronic device. The at least one program may include instructions that cause the electronic device to perform the methods according to various embodiments of the disclosure.

The programs (e.g., software modules or software) may be stored in non-volatile memories including a random access memory (RAM) and a flash memory, a read only memory (ROM), an electrically erasable programmable ROM (EEPROM), a magnetic disc storage device, a compact disc-ROM (CD-ROM), digital versatile discs (DVDs), other types of optical storage devices, or a magnetic cassette. Alternatively, any combination of some or all of the above-identified memories may form a memory in which the program is stored. Further, a plurality of such memories may be included in the electronic device.

In addition, the programs may be stored in an attachable storage device which is accessible through communication networks such as the Internet, Intranet, local area network (LAN), wide area network (WAN), storage area network (SAN), or a combination thereof. Such a storage device may access the electronic device via an external port. Further, a separate storage device on the communication network may access a portable electronic device.

In the above-described embodiments of the disclosure, a component may be expressed in the singular or the plural. However, the singular form or plural form is selected for convenience of description suitable for the presented situation, and the disclosure is not intended to be limited to a single element or multiple elements thereof. Further, either multiple elements expressed in the may be configured into a single element or a single element in the may be configured into multiple elements.

While the disclosure has been shown and described with reference to certain embodiments thereof, it will be understood by those skilled in the art that various changes in form and details may be made therein without departing from the scope of the disclosure. Therefore, the scope of the disclosure is not intended to be limited to the embodiments, but is defined by the appended claims and equivalents thereof.

What is claimed is:

1. A method of operating an electronic device including a transmitter and a receiver in a wireless communication system, the method comprising:
acquiring a signal passing through an intermediate path between the transmitter and the receiver;
estimating a phase change in the intermediate path, based on the signal and a reception signal predicted by a modeled system; and
determining in-phase/quadrature (I/Q) mismatch parameters indicating a mismatch of I components and Q components of the transmitter and the receiver from the phase change.

2. The method of claim 1, wherein the I/Q mismatch parameters include two or more of a gain mismatch parameter of the transmitter, a gain mismatch parameter of the receiver, a phase mismatch parameter of the transmitter, and a phase mismatch parameter of the receiver.

3. The method of claim 1, wherein the phase change is an angle that maximizes a sum of power of the acquired signal and power of the reception signal predicted by the modeled system.

4. The method of claim 1, wherein the intermediate path includes a first intermediate path and a second intermediate path.

5. The method of claim 4, wherein the first intermediate path connects a first node, before the transmitter within the electronic device reaches a power amplifier, after undergoing I/Q modulation, and a second node, before the receiver within the electronic device reaches I/Q demodulation, after undergoing low-noise amplification, and the second intermediate path connects two nodes equal to those of the first intermediate path and connected to the first intermediate path in parallel.

6. The method of claim 4, wherein the acquired signal includes a signal passing through the first intermediate path and a signal passing through the second intermediate path.

7. The method of claim 4, wherein the phase change includes a first phase change estimated, based on the signal passing through the first intermediate path and the reception signal predicted by the modeled system, and a second phase change estimated, based on the signal passing through the second intermediate path and the reception signal predicted by the modeled system.

8. The method of claim 7, further comprising:
calculating a first normalized power of the signal passing through the first intermediate path, based on the first phase change; and
calculating a second normalized power of the signal passing through the second intermediate path, based on the second phase change.

9. The method of claim 8, wherein determining the I/Q mismatch parameters of the transmitter and the receiver comprises determining the I/Q mismatch parameters, based on the first phase change, the second phase change, the first normalized power, and the second normalized power.

10. The method of claim 1, further comprising calibrating the I/Q mismatch of the transmitter and the receiver, based on the I/Q mismatch parameters.

11. An electronic device in a wireless communication system, the electronic device comprising:
a transmitter;
a receiver; and
at least one processor, configured to:
acquire a signal passing through an intermediate path between the transmitter and the receiver,
estimate a phase change in the intermediate path, based on the signal and a reception signal predicted by a modeled system, and
determine in-phase/quadrature (I/Q) mismatch parameters indicating a mismatch of I components and Q components of the transmitter and the receiver from the phase change.

12. The electronic device of claim 11, wherein the I/Q mismatch parameters include two or more of a gain mismatch parameter of the transmitter, a gain mismatch parameter of the receiver, a phase mismatch parameter of the transmitter, and a phase mismatch parameter of the receiver.

13. The electronic device of claim 11, wherein the phase change is an angle that maximizes a sum of power of the acquired signal and power of the reception signal predicted by the modeled system.

14. The electronic device of claim 11, wherein the intermediate path includes a first intermediate path and a second intermediate path.

15. The electronic device of claim 14, wherein the first intermediate path connects a first node, before the transmitter within the electronic device reaches a power amplifier, after undergoing I/Q modulation, and a second node, before the receiver within the electronic device reaches I/Q demodulation after undergoing low-noise amplification, and the second intermediate path connects two nodes equal to those of the first intermediate path and connected to the first intermediate path in parallel.

16. The electronic device of claim 14, wherein the acquired signal includes a signal passing through the first intermediate path and a signal passing through the second intermediate path.

17. The electronic device of claim 14, wherein the phase change includes a first phase change estimated, based on the signal passing through the first intermediate path and the reception signal predicted by the modeled system, and a second phase change estimated, based on the signal passing through the second intermediate path and the reception signal predicted by the modeled system.

18. The electronic device of claim 17, wherein the at least one processor is further configured to calculate first normalized power of the signal passing through the first intermediate path, based on the first phase change, and calculate second normalized power of the signal passing through the second intermediate path, based on the second phase change.

19. The electronic device of claim 18, wherein the at least one processor is further configured to determine the I/Q mismatch parameters, based on the first phase change, the second phase change, the first normalized power, and the second normalized power.

20. The electronic device of claim 11, further comprising:
a transmission calibrator; and
a reception calibrator,
wherein the at least one processor is further configured to calibrate the I/Q mismatch of the transmitter and the receiver, based on the I/Q mismatch parameters by controlling the transmission calibrator and the reception calibrator.
